(19) United States
(12) Patent Application Publication
(10) Pub. No.: US 2010/0001619 A1
(43) Pub. Date: Jan. 7, 2010

(54) PEROVSKITE-TYPE OXIDE SINGLE CRYSTAL AND METHOD OF MANUFACTURING THE SAME, COMPOSITE PIEZOELECTRIC MATERIAL, PIEZOELECTRIC VIBRATOR, ULTRASONIC PROBE, AND ULTRASONIC DIAGNOSTIC APPARATUS

(75) Inventors: Shigenorii Yuuya, Kaisei-machi (JP); Masayuki Suzuki, Kaisei-machi (JP); Masahiro Takata, Kaisei-machi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/487,245

(22) Filed: Jun. 18, 2009

(30) Foreign Application Priority Data
Jul. 4, 2008 (JP) 2008-175744

(51) Int. Cl. B06B 1/06; C30B 1/02; C01G 23/04; B32B 27/06; H01L 41/22

(52) U.S. Cl. 310/334; 117/9; 423/598; 428/697; 29/25.35

(57) ABSTRACT

A method of manufacturing a perovskite-type oxide single crystal having a desired composition and exhibiting excellent properties. The method includes the steps of: (a) forming a precursor of a perovskite-type oxide, at least a part of which is in an amorphous state, on a seed single crystal substrate to prepare a complex of the seed single crystal and the precursor, and (b) heat-treating the complex to induce solid phase epitaxy in the precursor, and thereby, forming a single crystal of the perovskite-type oxide.

### CROSS-REFERENCE TO RELATED APPLICATION

The present application claims priority from Japanese Patent Application No. 2008-175744 filed on Jul. 4, 2008, the contents of which are incorporated herein by reference in their entirety.

### BACKGROUND OF THE INVENTION

1. Field of the Invention

The present invention relates to a perovskite-type oxide single crystal and a method of manufacturing the same. Furthermore, the present invention relates to a composite piezoelectric material, a piezoelectric vibrator, an ultrasonic probe, and an ultrasonic diagnostic apparatus, structured by using such a perovskite-type oxide single crystal.

2. Description of a Related Art

Perovskite-type oxides, such as barium titanate (BaTiO₃) and lead zirconate titanate (PZT: PbZrₓTi₁₋ₓO₃), are widely used in a piezoelectric vibrator of an ultrasonic probe. In particular, ternary piezoelectric ceramic materials containing a perovskite-type complex compound, which is collectively referred to as a relaxor material, such as lead magnesium niobate (PMN: PbMg_{1/3}Nb_{2/3}O₃) or lead nickel niobate (PNN: PbNi_{1/3}Nb_{2/3}O₃), in the form of solid solution are widely used as the material for a piezoelectric vibrator due to its high piezoelectric constant.

The single crystal of a perovskite-type oxide containing such relaxor material and lead titanate is uniaxially polarized because it is a single crystal, and therefore, both its piezoelectric constant and electromechanical coupling coefficient are high. Thus, such a single crystal of a perovskite-type oxide attracts attention now as the material for a piezoelectric vibrator. If such a perovskite-type oxide single crystal is used as a material for a piezoelectric vibrator in an ultrasonic probe to be used for medical applications or for nondestructive testing, significant improvement in the resolution and sensitivity can be achieved.

If the perovskite-type oxide single crystal as described above is used, matching with a transmission and reception circuit can be improved because it has a relative dielectric constant equivalent to or higher than that of the conventional relaxor-based piezoelectric ceramic. Furthermore, since the perovskite-type oxide single crystal has acoustic impedance that is smaller as compared with the acoustic impedance of a typical ceramic material and that is closer to the acoustic impedance of a human body, the acoustic impedance matching can be also achieved easily.

In the ultrasonic probe, an array-type vibrator, in which a plurality of strip-shaped vibrators are arranged, is mostly used. Focusing, scanning, and so on of an ultrasonic beam are performed by the timing control of a voltage pulse applied to each of the vibrator elements. In the ultrasonic probe to be used for medical applications or for nondestructive testing, the operation frequency needs to be in a MHz range in order to achieve high resolution, and the size of one strip-shaped vibrator will be approximately 100 μm to 200 μm in width and approximately several hundred micrometers in height.

In such a strip-shaped vibrator, the electromechanical coupling coefficient of longitudinal vibration decreases by approximately ten percents as compared with the electromechanical coupling coefficient k33 of a rod-shaped piezoelectric element because the strip-shaped vibrator is restrained in horizontal expansion and contraction. In order to suppress a decrease in the electromechanical coupling coefficient in the strip-shaped vibrator, a composite structure, in which one vibrator is composed by combining rod-type piezoelectric elements with resin, i.e., the 1-3 composite, has been proposed. In the 1-3 composite, not only the electromechanical coupling coefficient is large as described above but also the acoustic impedance matching is achieved more easily because the acoustic impedance of the resin to be combined is small and the acoustic impedance as the vibrator is further reduced.

By the way, as a method of manufacturing an oxide single crystal, a melt process is known. However, the melt process has problems in that the manufacturing cost is high because the oxides typically have high melting points and thus a noble metal such as platinum is used as a skull crucible, and that the contamination with impurities is also inevitable during single crystal growth. Moreover, in oxide compounds, there are few congruent melting compositions, and if congruent melting compositions cannot be used, a target product cannot be obtained by directly single-crystallizing a melt. Then, under the present circumstances, a single crystal is grown by a flux growth method or a top-seeded solution growth method that uses a melt having different compositions. However, a single crystal fabricated by these methods also has problems in that a large crystal cannot be obtained, that it takes long time to grow a single crystal, and that there is a great loss of the raw material.

Further, a method of obtaining an oxide single crystal while in solid phase is also known. This method uses a polycrystalline oxide as the precursor of a single crystal, and utilizes the abnormal grain growth that occurs when this polycrystalline oxide is kept at a high temperature. If only an abnormal grain is caused to continue to grow in the polycrystal, a single crystal can be obtained without melting the polycrystal. However, the abnormal grain growth does not always occur in all the oxides. With the composition having the ratio of metallic elements derived from a crystal structure, a totally uniform grain growth will occur and the abnormal grain growth is unlikely to occur. As a result, a single crystal cannot be obtained. The techniques for circumventing this problem include a technique for inducing the abnormal grain growth at an interface between a polycrystal and a seed single crystal. For example, Yamamoto et al., “Fabrication of Barium Titanate Single Crystals by Solid-State Grain Growth”, Journal of the American Ceramic Society, 1994, vol. 77, No. 4, pp. 1107-1109 has disclosed a technique for inducing the abnormal grain growth at an interface between a polycrystal and a seed single crystal by using a composition having an excess of Ti in comparison with a composition having a ratio of Ba:Ti=1:1 in BaTiO₃.

Moreover, if a seed single crystal and a polycrystalline oxide are joined together and they are kept at a high temperature, then the grain growth of the polycrystalline oxide occurs in epitaxial form on the seed single crystal, which thus induces single crystallization. However, the epitaxial growth competes with the grain growth of the polycrystalline oxide, and the epitaxial growth will stop with the progress of the grain growth in a polycrystal portion. In order to circumvent this, Japanese Patent Application Publication JP-A-2-199094 has disclosed a method of single-crystallizing a polycrystalline ferrite while suppressing the abnormal grain growth by interposing a specific component at the junction interface between a single crystal and a polycrystal. Further, Japanese Patent Application Publication JP-P2003-523919A (International Publication WO 01/63021 A1) has disclosed a technique, in which the abnormal grain growth is promoted at the junction portion between a single crystal and a polycrystal while the abnormal grain growth is suppressed inside the polycrystal, by excessively adding a component to the polycrystal or by adding an additive for promoting the abnormal grain growth thereto.

However, with these methods, the obtained single crystal composition will also differ from a target composition because some of the metals are present in excess reflecting the composition of the precursor.

Moreover, it is difficult to fabricate a micro array of piezoelectric vibrators, and furthermore, with regard to the individual vibrator, a piezoelectric oxide structure such as the 1-3 composite structure by machining by using the obtained perovskite-type oxide single crystal. The piezoelectric oxide is very fragile, and will be immediately broken if a small crack occurs during machining. Even if the machining could be possible, a damaged layer, a micro crack, or the like occurs in the machined surface because the machined surface received stress during machining, and thus, the inherent properties of a piezoelectric element cannot be obtained.

### SUMMARY OF THE INVENTION

The present invention has been achieved in view of such problems. It is an object of the present invention to provide a perovskite-type oxide single crystal having a desired composition and exhibiting excellent properties. It is another object of the present invention to provide a composite piezoelectric material, a piezoelectric vibrator, an ultrasonic probe, and an ultrasonic diagnostic apparatus, using such a perovskite-type oxide single crystal.

In order to achieve the above-described objects, a method of manufacturing a perovskite-type oxide single crystal according to one aspect of the present invention includes the steps of: (a) forming a precursor of a perovskite-type oxide, at least a part of which is in an amorphous state, on a seed single crystal substrate to prepare a complex of the seed single crystal substrate and the precursor; and (b) heat-treating the complex to induce solid phase epitaxy in the precursor, and thereby, forming a single crystal of the perovskite-type oxide. Note that the amorphous state means an irregular state, not a crystallized state. However, the amorphous state has a short-range order although it does not have a long-range order as the crystal state has. Thermodynamically, the amorphous state means a state where the free energy is minimal (non-equilibrium metastable state).

According to the one aspect of the present invention, a single crystal thick film with a thickness of approximately 1 mm having a desired composition can be obtained by using a precursor having a composition of a target perovskite-type oxide single crystal, without interposing a specific component at an interface with a seed single crystal. If solid phase epitaxy is induced after micro-structuring the precursor by machining or the like, then an array-type vibrator employing a piezoelectric single crystal can be obtained economically and easily. Moreover, the oxide single crystal structure formed in this manner can serve as a high-performance composite piezoelectric material (1-3 composite) by being combined with a resin, and a piezoelectric vibrator or an ultrasonic probe can be constructed by using such a composite piezoelectric material, and furthermore, an ultrasonic diagnostic apparatus can be constructed by using such an ultrasonic probe.

Incidentally, it is known that a single crystal of a piezoelectric oxide containing zirconium (Zr) cannot be produced by using the melt process because zirconium will phase-separate as the zirconium oxide when the piezoelectric oxide containing zirconium is melted. However, the method of manufacturing a perovskite-type oxide single crystal according to the present invention can be applied to the single crystallization process of the piezoelectric oxide containing zirconium.

### BRIEF DESCRIPTION OF THE DRAWINGS

FIG. 1 is a flow chart showing a method of manufacturing a perovskite-type oxide single crystal and a product using the same, according to an embodiment of the present invention;

FIG. 2 is a conceptual diagram for illustrating a structure of an intermediate complex in an embodiment of the present invention;

FIGS. 3A to 3C are views illustrating the process from formation of a microstructure by machining to single crystallization thereof in an embodiment of the present invention;

FIG. 4 is a flow chart showing a processing procedure in Example 1 of the method of manufacturing a perovskite-type oxide single crystal according to the present invention;

FIG. 5 is a perspective view showing a piezoelectric vibrator according to a first embodiment of the present invention;

FIG. 6 is a side view showing a piezoelectric vibrator according to a second embodiment of the present invention;

FIG. 7 is a perspective view showing an internal structure of an ultrasonic probe according to an embodiment of the present invention; and

FIG. 8 is a block diagram showing a configuration of an ultrasonic diagnostic apparatus according to an embodiment of the present invention.

### DESCRIPTION OF THE PREFERRED EMBODIMENTS

Hereinafter, embodiments of the present invention will be described in detail with reference to the accompanying drawings.

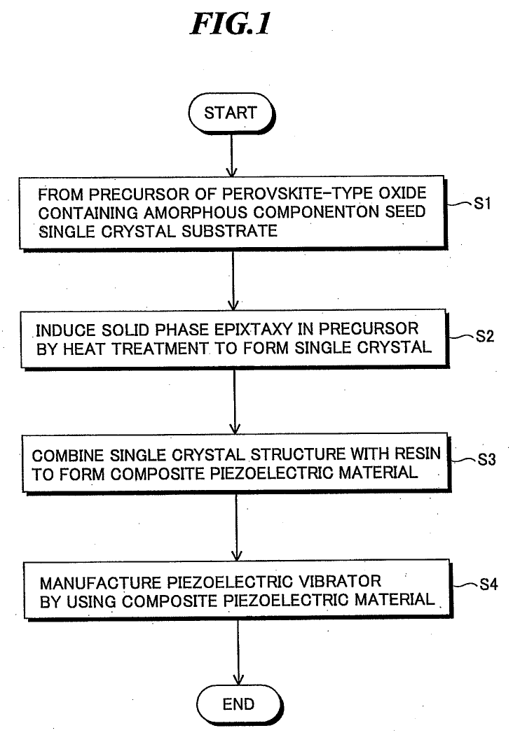

FIG. 1 is a flow chart showing a method of manufacturing a perovskite-type oxide single crystal and a product using the same, according to an embodiment of the present invention.

At step S1 as shown in FIG. 1, a precursor of a perovskite-type oxide containing an amorphous component is formed on a seed single crystal substrate to prepare a complex of the seed single crystal substrate and the precursor.

The perovskite-type oxide is an oxide having a perovskite-type crystal structure, in which a plurality of octahedrons formed of oxygen are arranged with their vertices shared with each other, and elements are located at a center of eight octahedrons and at a center of each octahedron. Here, assuming that an element located at the center of eight octahedrons is denoted by an A site element, and an element located at the center of each octahedron is denoted by a B site element, then the general formula of the perovskite-type crystal structure is represented by ABO₃. The coordination number of oxygen around the A site element is 12, and the coordination number of oxygen around the B site element is 6.

As the precursor, a perovskite-type oxide (precursor oxide), at least a part of which is in an amorphous state, is used, and it is preferable that a mixture of microcrystal (microcrystal oxide) and an amorphous part (amorphous oxide) is used, for example. Furthermore, in the mixture of the microcrystal and the amorphous part, the amorphous part is preferably produced from a chemical liquid-phase solution containing a metallic component of the microcrystal oxide. This is because the amorphous part, that is a pyrolysate of the chemical liquid-phase solution, is firmly attached to the microcrystal, and is therefore more likely to induce single crystallization. Incidentally, if the grain size of the microcrystal is too large, then single crystallization will not proceed. In order for the single crystallization of the precursor oxide to smoothly proceed, the grain size of the microcrystal is preferably equal to or less than 5 μm, more preferably equal to or less than 2 μm.

First, single-phase microcrystal grain of a perovskite-type oxide is deposited onto a seed single crystal substrate. The seed single crystal substrate is a substrate formed of a perovskite-type single crystal having a grating constant which is substantially equal to that of a target oxide single crystal. The difference in the grating constants at room temperature is preferably equal to or less than 5% between the single-phase microcrystal grain and the seed single crystal. For example, single-phase microcrystal grain (single-phase powder) of a perovskite-type oxide is deposited in a predetermined shape on the seed single crystal substrate to form a compact, and this compact is enclosed in a rubber bag, and then, the microcrystal grain is pressed onto the seed single crystal by using the cold isostatic press (CIP) method to form a pressed powder compact.

Next, the pressed powder compact is impregnated with a chemical liquid-phase solution, which is formulated such that the metal composition ratio may become the same as that of the perovskite single-phase powder, and then, the solvent component is evaporated. Furthermore, the resultant pressed powder compact is heated to pyrolyze an organic acid salt component and form an amorphous oxide. In this manner, a component of the chemical liquid-phase solution is decomposed by the heat treatment and turned into the amorphous oxide. As a result, an intermediate complex having a precursor oxide, in which the amorphous part fills around the microcrystal, joined onto the seed single crystal substrate is formed. Alternatively, the intermediate complex of the precursor and the seed single crystal may be formed by joining a precursor of a perovskite-type oxide, at least a part of which is in an amorphous state, onto the seed single crystal substrate.

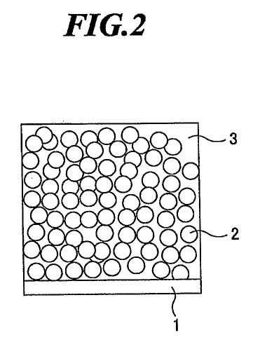

FIG. 2 is a conceptual diagram for illustrating a structure of an intermediate complex in an embodiment of the present invention. Microcrystals 2 of a perovskite-type oxide is deposited on a seed single crystal substrate 1, and the gap between the microcrystals 2 is filled with an amorphous oxide 3.

In the chemical liquid-phase solution, inorganic acid salts or organic acid salts of various kinds of metallic elements, alkoxides, and a mixture of these can be used. As the solvent, an appropriate solvent having solubility relative to various kinds of salts can be used. The metal composition of the chemical liquid-phase solution may be the same as the composition of the precursor oxide, or may further contain a component that promotes subsequent sintering or single crystallization. A commercially available organic acid salt solution (for example, MOD material of KOJUNDO CHEMICAL LABORATORY CO., LTD.) can be used.

The chemical liquid-phase solution can be impregnated into the pressed powder compact by a method of immersing the pressed powder compact into a solution or dropping a solution onto the pressed powder compact. In order to effectively perform impregnation, vacuum is preferably used at the same time. After impregnation, the solution is volatilized to pyrolyze the salt or alkoxide. Depending on the solvent and salt of the chemical liquid-phase solution, the drying temperature and pyrolysis temperature are preferably within the range of 50° C. to 150° C. and the range of 150° C. to 500° C., respectively. The vacuum impregnation and pyrolysis of the chemical liquid-phase solution are repeated until the pressed powder compact is filled and saturated with the amorphous oxide and the solution becomes no longer impregnated into the pressed powder compact.

At step S2 as shown in FIG. 1, a heat treatment of maintaining the intermediate complex having the precursor oxide deposited on the seed single crystal substrate at a high temperature is performed to induce solid phase epitaxy in the precursor and single-crystallize the precursor. Thus, a single crystal of a perovskite-type oxide is produced.

Between step S1 and step S2, a portion of the precursor oxide may be micro-structured in advance by machining, and thereafter, the precursor may be single-crystallized at step S2. Since the amorphous part, that is a pyrolysate of the chemical liquid-phase solution, is firmly attached to the microcrystal, the precursor that employs the amorphous part derived from the chemical liquid-phase solution has high strength and good processability, and thus can be minutely structured by machining such as dicing.

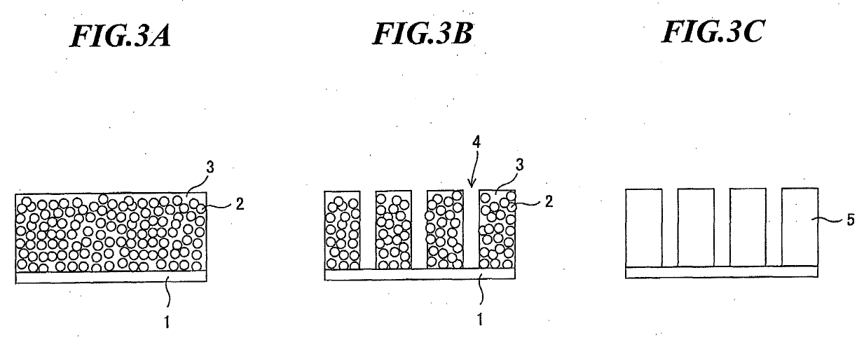

FIGS. 3A to 3C are views illustrating the process from formation of a microstructure by machining to single crystallization in an embodiment of the present invention. In a precursor portion of the intermediate complex formed by depositing the precursor containing the perovskite-type oxide microcrystal 2 and the amorphous oxide 3 on the seed single crystal substrate 1, as shown in FIG. 3A, a narrow groove 4 is formed to the extent that it reaches the surface of the seed single crystal substrate 1 as shown in FIG. 3B by machining such as dicing so as to form a microstructure of the precursor. This microstructure is heat-treated to induce solid phase epitaxy and single crystallization whereby a structure of single crystal 5 as shown in FIG. 3C is formed. For example, if the precursor portion is diced in mutually orthogonal two directions, a portion remaining as a single crystal becomes a micro-column structure, in which square poles are arrayed and each of the square poles has an upright cross section as a square having a large aspect ratio.

Such a single crystal structure having a micro-column structure, in which micro columns of a large aspect ratio are arrayed, can serve as a composite piezoelectric material (1-3 composite) by impregnating a thermosetting resin such as an epoxy resin, a urethane resin, or a phenol resin between these micro columns and curing the thermosetting resin (step S3 as shown in FIG. 1). The composite piezoelectric material obtained at step S3 is ground to a predetermined thickness according to need, and then, electrodes are formed on both sides thereof and the composite piezoelectric material is polarized. Thereby, a piezoelectric vibrator is manufactured (step S4 as shown in FIG. 1).

Hereinafter, examples of the method of manufacturing the perovskite-type oxide single crystal according to the present invention will be described.

### EXAMPLE 1

In Example 1, a single crystal of commercially available PMN (lead magnesium niobate)-PT (lead titanate) with 0.7 PMN-0.3 PT composition and along the (100) plane is used as the seed single crystal substrate, and perovskite single-phase powder with an average grain size of 1 μm and 0.7PMN-0.3 PT composition is used as the oxide raw material to be single-crystallized, and furthermore, an organic acid salt solution is used. The organic acid salt solution is formulated such that the metal composition ratio may become the same as that of the perovskite single-phase powder.

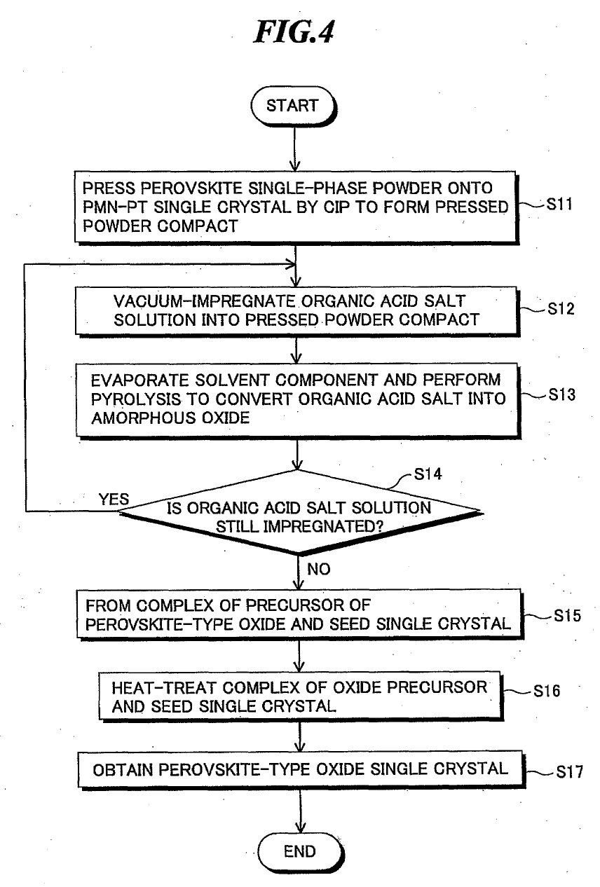

FIG. 4 is a flow chart showing a processing procedure in Example 1 of the method of manufacturing a perovskite-type oxide single crystal according to the present invention. First, the PMN-PT single crystal and the perovskite single-phase powder are sealed in a rubber bag, and the perovskite single-phase powder is pressed onto the single crystal by a cold isostatic press (CIP) of 200 MPa to form a pressed powder compact (step S11). Furthermore, the organic acid salt solution is dropped onto the perovskite single-phase powder portion of the pressed powder compact, which is taken out of the bag, in vacuum to vacuum-impregnate the organic acid salt solution into the pressed powder compact (step S12).

The pressed powder compact impregnated with the solution is dried at 120° C. to evaporate the solvent component, and furthermore, the organic acid salt component is pyrolyzed for 5 minutes at 300° C. to convert the organic acid salt into an amorphous oxide (step S13). The processes of step S12 and step S13 are repeated until the organic acid salt solution would not be impregnated into the pressed powder compact any more (step S14), thereby forming a complex of the precursor of the perovskite-type oxide and the seed single crystal (step S15). Heat treatment for 5 hours at 1250° C. is performed on the formed complex of the precursor oxide and the seed single crystal (step S16), and then, the portion of the pressed powder compact with 0.7 PMN-0.3 PT composition is single-crystallized at a thickness of approximately 2 mm from the interface portion of the seed single crystal. Thus, a perovskite-type oxide single crystal is obtained (step S17).

### EXAMPLE 2

In Example 2, with the thickness of the pressed powder compact set to be 0.5 mm, the same processing as that of Example 1 is performed until step S15, which thus forms a complex of the precursor oxide and the seed single crystal. Thereafter, dicing is performed on the surface of the pressed powder compact of the complex by using a blade having a thickness of 25 μm, whereby square poles, each having a length of one side of 30 μm and a height of 200 μm, are formed at a pitch of 60 μm (the interval between the square poles is 30 μm). Furthermore, when heat treatment is performed for 5 hours at 1300° C., single crystallization occurred up to the surface portions of the square poles.

### EXAMPLE 3

In Embodiment 3, the same processing as that of Example 1 is performed except that the average grain size of the perovskite single-phase powder with 0.7 PMN-0.3 PT composition is 5 μm, and thereby, single crystallization occurred at a thickness of approximately 1 mm from the interface portion of the seed single crystal. When the conditions for solid phase epitaxial growth are changed to a longer time or a higher temperature, the thickness of the single crystal portion does not change but the increase in the crystal grain diameter of a portion that has not been single-crystallized is observed.

### COMPARATIVE EXAMPLE 1

The same heat treatment as that of step S16 is immediately performed on the pressed powder compact obtained at step S11 in Example 1 without performing the organic acid salt impregnation treatment of steps S12 to S15, and then, single crystallization in the pressed powder compact portion is not observed. When the condition for solid phase epitaxial is changed to 1300° C. in the temperature of heat treatment, the pressed powder compact is partially single-crystallized at the interface but its thickness is 50 μm at a maximum. Moreover, machining similar to that of Example 2 is tried before the heat treatment of step S16, but all of the micro-column structures are destroyed during the machining.

### COMPARATIVE EXAMPLE 2

Only the perovskite single-phase powder of 0.7 PMN-0.3 PT composition used in Example 1 is CIP-molded, and then, sintered for 3 hours at 1200° C. The crystal grain diameter of the obtained sintered body is 3 μm on an average. One of the surfaces of the sintered body is mirror-polished, which is then stacked with the seed single crystal. The stacked sintered body, to which a surface pressure of 100 kPa is being applied by a weight in order to maintain the adhesion, is subjected to heat treatment for 5 hours at 1300° C. Similarly to Comparative Example 1, the pressed powder compact is partially single-crystallized at the interface but its thickness is 50 μm at a maximum.

Next, a piezoelectric vibrator according to a first embodiment of the present invention will be described.

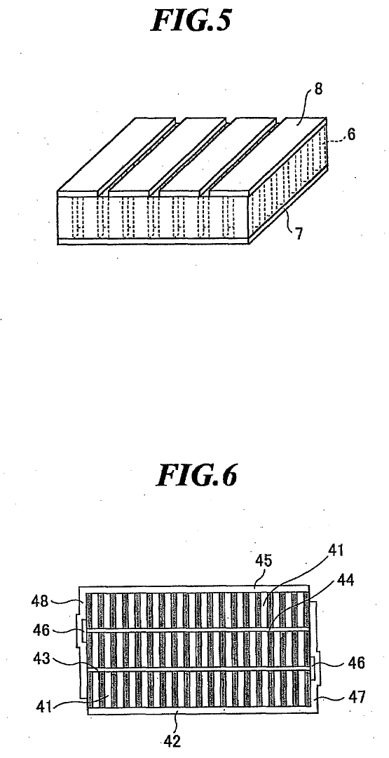

FIG. 5 is a perspective view showing the piezoelectric vibrator according to the first embodiment of the present invention. A common electrode 7 is formed on one surface of a composite piezoelectric material 6, and a strip-shaped individual electrode 8 is formed on another surface of the composite piezoelectric material 6. Here, an independent piezoelectric vibrator is formed for each individual electrode 8. The electrodes can be formed by depositing a metal, such as gold (Au), platinum (Pt), or nickel (Ni), on the surface of the composite piezoelectric material 6 by commonly-used metallic coating, such as electroless deposition, vacuum deposition, or sputtering. Moreover, aluminium (Al), chromium (Cr), titanium (Ti), or the like may be used as an interlayer in order to secure the adhesion of the electrodes. The polarization process of the composite piezoelectric material 6 is performed by applying a predetermined voltage between the common electrode 7 and the individual electrode 8 in insulating oil.

Next, a piezoelectric vibrator according to a second embodiment of the present invention will be described.

FIG. 6 is a side view showing the piezoelectric vibrator according to the second embodiment of the present invention. In the second embodiment, a multilayered type piezoelectric vibrator is constructed by alternatively stacking a plurality of composite piezoelectric materials (1-3 composite) and a plurality of electrodes. As shown in FIG. 6, the multilayered type piezoelectric vibrator comprises a plurality of composite piezoelectric material layers 41, a lower electrode layer 42, internal electrode layers 43 and 44 alternatively inserted between the plurality of composite piezoelectric material layers 41, an upper electrode layer 45, an insulating film 46, and side surface electrodes 47 and 48, and has a multilayered structure.

The lower electrode layer 42 is connected to the side surface electrode 47 but isolated from the side surface electrode 48. The upper electrode layer 45 is connected to the side surface electrode 48 but isolated from the side surface electrode 47. Moreover, the internal electrode layer 43 is connected to the side surface electrode 48, but isolated from the side surface electrode 47 by the insulating film 46. On the other hand, the internal electrode layer 44 is connected to the side surface electrode 47, but isolated from the side surface electrode 48 by the insulating film 46. By forming a plurality of electrodes of the ultrasonic transducer in this manner, three sets of electrodes for applying an electric field to a three-layered composite piezoelectric material layer 41 are connected in parallel. Incidentally, the number of layers of the composite piezoelectric material layer is not limited to three layers, but may be two layers, or four layers or more.

In such a multilayered type piezoelectric vibrator, the electrical impedance will decrease because the area of opposing electrodes increases more than that of a single-layer type piezoelectric vibrator. Therefore, as compared with a single-layer type piezoelectric vibrator with the same size, such a multilayered type piezoelectric vibrator operates efficiently with respect to the applied voltage. Specifically, if the number of piezoelectric element layers is set to be N, the number of piezoelectric element layers becomes N times that of a single-layered type piezoelectric vibrator and the thickness of each of the piezoelectric element layers becomes 1/N time that of the single-layered type piezoelectric vibrator. Accordingly, the electrical impedance of the piezoelectric vibrator becomes 1/N². Therefore, the electrical impedance of a piezoelectric vibrator can be adjusted by increasing or decreasing the number of stacked layers of the piezoelectric element layer. As a result, electrical impedance matching with a driving circuit or a signal cable can be easily achieved, and the sensitivity can be improved.

Next, an ultrasonic probe according to an embodiment of the present invention will be described.

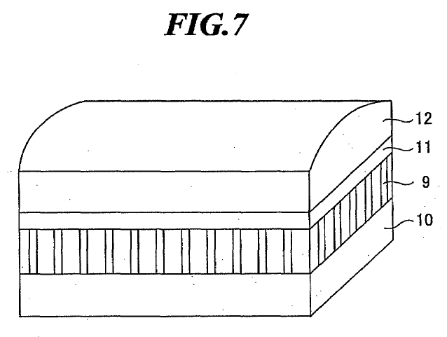

FIG. 7 is a perspective view showing an internal structure of the ultrasonic probe according to an embodiment of the present invention. The ultrasonic probe can be fabricated by combining a vibrator array 9 employing the polarized composite piezoelectric material (1-3 composite), a backing material 10 disposed on a first surface of the vibrator array 9, at least one acoustic matching layer 11 disposed on a second surface opposite to the first surface of the vibrator array 9, and an acoustic lens 12, and furthermore, by connecting wirings to the vibrator array 9 by using a well-known method. Further, in the ultrasonic probe, a multilayered type piezoelectric vibrator constructed by stacking a plurality of composite piezoelectric materials and a plurality of electrodes may be used.

Next, an ultrasonic diagnostic apparatus according to an embodiment of the present invention will be described.

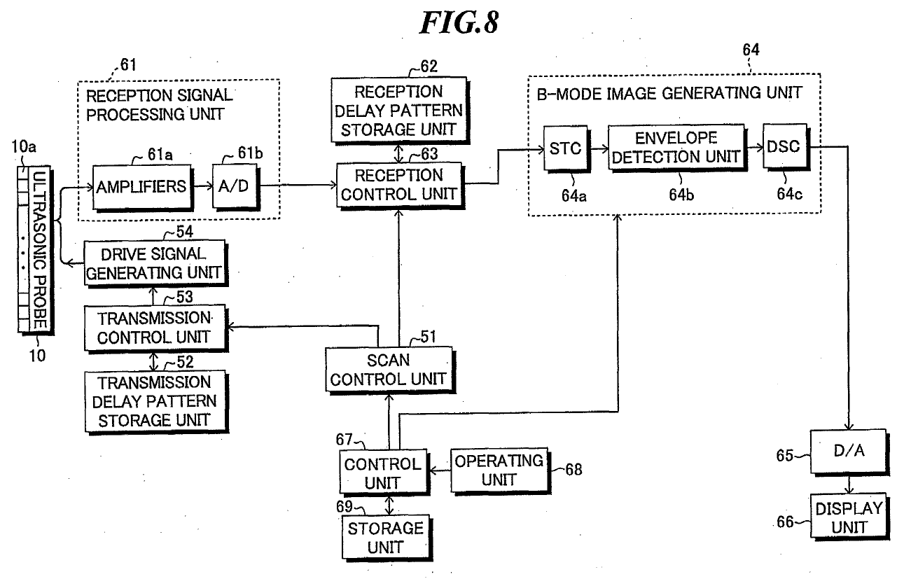

FIG. 8 is a block diagram showing a configuration of the ultrasonic diagnostic apparatus according to an embodiment of the present invention. This ultrasonic diagnostic apparatus comprises an ultrasonic probe according to an embodiment of the present invention and the ultrasonic diagnostic apparatus main body. The ultrasonic diagnostic apparatus main body includes a scan control unit 51, a transmission delay pattern storage unit 52, a transmission control unit 53, a drive signal generating unit 54, a reception signal processing unit 61, a reception delay pattern storage unit 62, a reception control unit 63, a B-mode image generating unit 64, a D/A converter 65, a display unit 66, a control unit 67, an operation unit 68, and a storage unit 69.

Here, the transmission delay pattern storage unit 52 to the drive signal generating unit 54 constitute a drive signal supply means for supplying drive signals to a vibrator array of ultrasonic probe 50, and the reception signal processing unit 61 to the B-mode image generating unit 64 constitute a signal processing means that produces image data representing an ultrasonic image by processing reception signals outputted from the vibrator array of ultrasonic probe 50.

The ultrasonic probe 50 comprises a plurality of ultrasonic transducers 50a constituting a one-dimensional or two-dimensional transducer array (vibrator array). These ultrasonic transducers 50a send an ultrasonic wave based on applied drive signals, and receive propagating ultrasonic echoes to output reception signals.

The scan control unit 51 sequentially sets the transmission direction of an ultrasonic beam and the reception direction of ultrasonic echoes. The transmission delay pattern storage unit 52 stores a plurality of transmission delay patterns to be used in forming an ultrasonic beam. The transmission control unit 53 selects one transmission delay pattern from among the plurality of transmission delay patterns stored in the transmission delay pattern storage unit 52 according to the transmission direction set in the scan control unit 51, and sets delay times to be provided to drive signals for the plurality of ultrasonic transducers 50a, respectively, based on the selected transmission delay pattern. Alternatively, the transmission control unit 53 may set delay times such that the ultrasonic waves simultaneously transmitted from the plurality of ultrasonic transducers 50a may reach the entire imaging area of an object to be inspected.

The drive signal generating unit 54 comprises a plurality of pulsers corresponding to the plurality of ultrasonic transducers 50a, for example. The drive signal generating unit 54 supplies drive signals to the ultrasonic probe 50 according to the delay times set by the transmission control unit 53 such that the ultrasonic waves transmitted from the plurality of ultrasonic transducers 50a may form an ultrasonic beam. Alternatively, the drive signal generating unit 54 supplies drive signals to the ultrasonic probe 50 such that the ultrasonic waves simultaneously transmitted from the plurality of ultrasonic transducers 50a may reach the entire imaging region of an object to be inspected.

The reception signal processing unit 61 includes a plurality of amplifiers (preamplifiers) 61a and a plurality of A/D converters 61b corresponding to the plurality of ultrasonic transducers 50a. The reception signal outputted from the ultrasonic transducer 50a is amplified in the amplifier 61a, and an analog reception signal outputted from the amplifier 61a is converted into a digital reception signal by the A/D converter 61b. The A/D converters 61b output the digital reception signals to a reception control unit 63.

The delay pattern storage unit 62 stores a plurality of reception delay patterns to be used in performing reception focus processing on the reception signals outputted from the plurality of ultrasonic transducers 50a. The reception control unit 63 selects one reception delay pattern from among the plurality of reception delay patterns stored in the reception delay pattern storage unit 62 based on the reception directions set in the scan control unit 51, and performs the reception focus processing by providing delays to the reception signals based on the selected reception delay pattern, and adding the resultant reception signals to one another. By this reception focus processing, a sound ray signal, in which the focus of the ultrasonic echoes is narrowed, is formed.

The B-mode image generating unit 64 generates a B-mode image signal as tomographic image information on tissues within the object based on the sound ray signal formed by the reception control unit 63. The B-mode image generating unit 64 includes an STC (sensitivity time control) unit 64a, an envelope detection part 64b, and a DSC (digital scan converter) 64c.

The STC unit 64a performs correction of attenuation due to a distance on the sound ray signal formed by the reception control unit 63 depending on the depth of the reflection position of ultrasonic waves. The envelope detection part 64b performs envelope detection processing on the sound ray signal corrected by the STC unit 64a to generate an envelope signal. The DSC 64c converts (raster-converts) the envelope signal generated by the envelope detection part 624b into an image signal that follows the ordinary scan mode of television signals, and performs necessary image processing such as gradation processing to generate a B-mode image signal.

The D/A converter 65 converts the digital image signal outputted from the B-mode image generating unit 64 into an analog image signal. The display unit 66 includes a display device, for example such as a CRT or an LCD, and displays a diagnostic image based on the analog image signal.

The control unit 67 controls the scan control unit 51, the B-mode image generating unit 64, and so on in accordance with the operation of an operator using the operation unit 68. In this embodiment, the scan control unit 51, the transmission control unit 53, the reception control unit 63, the B-mode image generating unit 64, and the control unit 67 are configured by a CPU and software (program), but these may be configured by digital circuits or analog circuits. The software (program) is stored in the storage unit 69. A flexible disk, an MO, an MT, a RAM, a CD-ROM, a DVD-ROM, or the like other than a built-in hard disk can be used as the recording medium in the storage unit 69.

1. A method of manufacturing a perovskite-type oxide single crystal, said method comprising the steps of:
(a) forming a precursor of a perovskite-type oxide, at least a part of which is in an amorphous state, on a seed single crystal substrate to prepare a complex of said seed single crystal substrate and said precursor; and
(b) heat-treating said complex to induce solid phase epitaxy in said precursor, and thereby, forming a single crystal of said perovskite-type oxide.

2. The method according to claim 1, wherein said precursor contains microcrystal of said perovskite-type oxide in addition to an amorphous part.

3. The method according to claim 2, wherein an average grain size of said microcrystal is not larger than 5 μm.

4. The method according to claim 2, wherein step (a) includes forming a precursor containing microcrystal and an amorphous part by impregnating a chemical liquid-phase solution into a compact of microcrystal grain of a perovskite-type oxide and decomposing a component of the chemical liquid-phase solution by heat treatment.

5. The method according to claim 1, further comprising the step of:
micro-structuring said precursor by machining between step (a) and step (b).

6. The method according to claim 2, wherein said seed single crystal substrate has a perovskite-type crystal structure having a grating constant which differs from that of the microcrystal of said precursor by no larger than 5% at room temperature.

7. A perovskite-type oxide single crystal manufactured by the method according to claim 1.

8. The perovskite-type oxide single crystal according to claim 7, wherein said perovskite-type oxide contains lead (Pb).

9. A composite piezoelectric material comprising:
a plurality of piezoelectric elements each having a perovskite-type oxide single crystal manufactured by the method according to claim 1; and
a resin filling at least a space between said plurality of piezoelectric elements.

10. A piezoelectric vibrator comprising:
a composite piezoelectric material including a plurality of piezoelectric elements each having a perovskite-type oxide single crystal manufactured by the method according to claim 1, and a resin filling at least a space between said plurality of piezoelectric elements; and
a plurality of electrodes provided at both ends of said composite piezoelectric material.

11. A piezoelectric vibrator comprising:
a first electrode layer and a second electrode layer; and
a plurality of composite piezoelectric material layers alternatively stacked with at least one internal electrode layer between said first electrode layer and said second electrode layer, each of said plurality of composite piezoelectric material layers including a plurality of piezoelectric elements each having a perovskite-type oxide single crystal manufactured by the method according to claim 1, and a resin filling at least a space between said plurality of piezoelectric elements.

12. An ultrasonic probe comprising:
a vibrator array employing a composite piezoelectric material including a plurality of piezoelectric elements each having a perovskite-type oxide single crystal manufactured by the method according to claim 1, and a resin filling at least a space between said plurality of piezoelectric elements;
a backing material disposed on a first surface of said vibrator array; and
at least one acoustic matching layer disposed on a second surface opposite to the first surface of said vibrator array.

13. An ultrasonic diagnostic apparatus comprising:
an ultrasonic probe including a vibrator array employing a composite piezoelectric material including a plurality of piezoelectric elements each having a perovskite-type oxide single crystal manufactured by the method according to claim 1, and a resin filling at least a space between said plurality of piezoelectric elements;
drive signal supply means for supplying drive signals to said vibrator array; and
signal processing means for processing reception signals outputted from said vibrator array to generate an image signal representing an ultrasonic image.
